(19) United States
(12) Patent Application Publication
(10) Pub. No.: US 2026/0293406 A1
(43) Pub. Date: Sep. 24, 2026

(54) Display panel and display device

(71) Applicant: Wuhan Tianma MicroElectronics Co., Ltd. Shanghai Branch., Shanghai (CN)

(72) Inventor: Wei Shi, Shanghai (CN)

(21) Appl. No.: 19/244,756

(22) Filed: Jun. 20, 2025

(30) Foreign Application Priority Data
Mar. 20, 2025 (CN) 202510341277.9

(51) Int. Cl. H10H 29/853; H10H 29/855; H10K 59/80

(52) U.S. Cl. CPC H10H 29/853; H10H 29/855; H10K 59/873; H10K 59/8793

(57) ABSTRACT

A display panel and a display device are provided. The display panel includes a substrate, a display function layer, a first insulating layer, a second insulating layer, a polarizer, a first protective layer, and a second protective layer. The display panel has a display area and a first non-display area. The first non-display area includes a binding area. Along the first direction, the polarizer, the second insulating layer, and the first insulating layer do not overlap with the binding area. The first protective layer is located in the first non-display area. Along a first direction, the first protective layer overlaps with the second insulating layer, the first insulating layer and the binding area. The second protective layer is located on a side of the polarizer away from the substrate and covers the polarizer. Along the first direction, the second protective layer at least partially overlaps the first protective layer.

### CROSS-REFERENCE TO RELATED APPLICATION

This application claims the priority of Chinese Patent Application No. 202510341277.9, filed on Mar. 20, 2025, the content of which is incorporated herein by reference in its entirety.

### TECHNICAL FIELD

The present disclosure generally relates to the field of display technology and, more particularly, relates to a display panel and a display device.

### BACKGROUND

With the continuous development of science and technology, more and more display products, such as mobile phones, tablets, laptops, and smart wearable devices, are widely used in people's daily lives and work, bringing great convenience to people's daily lives and work, and becoming indispensable tools for people today.

Packaging reliability is one of important indicators for evaluating performance of display products. How to improve the packaging reliability of display products to improve stability of overall performance of the products has become one of technical problems that needs to be solved at this stage.

### SUMMARY

One aspect of the present disclosure provides a display panel. The display panel includes a substrate, a display function layer, a first insulating layer, a second insulating layer, a polarizer, a first protective layer, and a second protective layer. Along a first direction, the first insulating layer is disposed on a side of the display function layer away from the substrate, the second insulating layer is disposed on a side of the first insulating layer away from the substrate, and the polarizer is disposed on a side of the second insulating layer away from the substrate, wherein the first direction is perpendicular to a plane where the substrate is located. The display panel has a display area and a first non-display area located on one side of the display area along a second direction. The first non-display area includes a binding area. The polarizer is located in the display area and at least a portion of the first non-display area. The second insulating layer and the first insulating layer are located in the display area and at least a portion of the first non-display area. Along the first direction, the polarizer, the second insulating layer, and the first insulating layer do not overlap with the binding area. The first protective layer is located in the first non-display area. Along the first direction, the first protective layer is at least located on the side of the second insulating layer away from the substrate, and overlaps with the second insulating layer, the first insulating layer, and the binding area. The second protective layer is located on a side of the polarizer away from the substrate and covers the polarizer; and along the first direction, the second protective layer overlaps with at least part of the first protective layer.

Another aspect of the present disclosure provides a display device including the above-mentioned display panel. Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a top view of an exemplary display panel consistent with various disclosed embodiments in the present disclosure.

FIG. 2 illustrates a cross-sectional view of a display panel along an AA direction in FIG. 1 consistent with various disclosed embodiments in the present disclosure.

FIG. 3 illustrates a cross-sectional view of a display panel along a BB direction in FIG. 1 consistent with various disclosed embodiments in the present disclosure.

FIG. 4 illustrates a schematic diagram of a film layer after a flip chip film is bent consistent with various disclosed embodiments in the present disclosure.

FIG. 5 illustrates a schematic diagram of film layers of a display panel before reliability testing.

FIG. 6 illustrates a schematic diagram of film layers of a display panel after reliability testing.

FIG. 7 illustrates a schematic diagram of film layers of a display panel after reliability testing consistent with various disclosed embodiments in the present disclosure.

FIG. 8 illustrates a top view of a relationship between a polarizer and a first protective layer consistent with various disclosed embodiments in the present disclosure.

FIG. 9 illustrates a local view of a polarizer consistent with various disclosed embodiments in the present disclosure.

FIG. 10 illustrates another local view of a polarizer consistent with various disclosed embodiments in the present disclosure.

FIG. 11 illustrates a top view of another exemplary display panel consistent with various disclosed embodiments in the present disclosure.

FIG. 12 illustrates a cross-sectional view of an exemplary display panel along a CC direction in FIG. 11 consistent with various disclosed embodiments in the present disclosure.

FIG. 13 illustrates a schematic diagram of film layers when a polarizer is retracted inward, consistent with various disclosed embodiments in the present disclosure.

FIG. 14 illustrates a top view of another exemplary display panel consistent with various disclosed embodiments in the present disclosure.

FIG. 15 illustrates a planar view of another exemplary display panel consistent with various disclosed embodiments in the present disclosure.

FIG. 16 illustrates a top view of another exemplary display panel consistent with various disclosed embodiments in the present disclosure.

FIG. 17 illustrates a cross-sectional view of a display panel along a DD direction in FIG. 16 consistent with various disclosed embodiments in the present disclosure.

FIG. 18 illustrates another cross-sectional view of a display panel along a DD direction in FIG. 16 consistent with various disclosed embodiments in the present disclosure.

FIG. 19 illustrates a top view of another exemplary display panel consistent with various disclosed embodiments in the present disclosure.

FIG. 20 illustrates a cross-sectional view along an EE′ direction of a display panel in FIG. 18 consistent with various disclosed embodiments in the present disclosure.

FIG. 21 illustrates another cross-sectional view along an EE′ direction of a display panel in FIG. 18 consistent with various disclosed embodiments in the present disclosure.

FIG. 22 illustrates an exemplary display device consistent with various disclosed embodiments in the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted. Further, in the present disclosure, the disclosed embodiments and the features of the disclosed embodiments may be combined under conditions without conflicts. It is apparent that the embodiments described are some but not all of the embodiments of the present disclosure. Based on the disclosed embodiments, those ordinarily skilled in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width, and depth should be considered during practical fabrication.

In the present disclosure, terms such as “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential”, etc., indicate orientations or positional relationships based on the orientations or positional relationships shown in the accompanying drawings, and are only for the convenience of describing the present disclosure and simplifying the description, and do not indicate or imply that the device or element referred to must have a specific orientation, be constructed and operated in a specific orientation, and therefore should not be understood as limiting the present disclosure.

In the present disclosure, relational terms such as first and second are only used to distinguish one entity or operation from another entity or operation, and do not necessarily require or imply any actual relationship between these entities or operations or order. Moreover, the terms “including”, “comprising” or any other variants thereof are intended to cover non-exclusive inclusion, such that a process, method, article, or device that includes a series of elements includes not only those elements, but also those that are not explicitly listed or also include elements inherent to this process, method, article or equipment. If there are no more restrictions, the elements defined by the sentence “including . . . ” do not exclude the existence of other same elements in the process, method, article, or equipment that includes the elements.

It should be understood that when describing the structure of a component, when a layer or region is referred to as being “on” or “above” another layer or another region, the layer or region may be directly on the other layer or region, or indirectly on the other layer or region, for example, layers/components between the layer or region and another layer or another region. And, for example, when the component is reversed, the layer or region may be “below” or “under” the other layer or region. In the present disclosure, the term “electrical connection” refers to that two components are directly electrically connected with each other, or the two components are electrically connected via one or more other components.

In the present disclosure, unless otherwise clearly specified and limited, the terms “installed”, “connected”, “fixed” and the like appear, should be understood in a broad sense. For example, it can be a fixed connection, a detachable connection, or an integrated connection; it can be a mechanical connection or an electrical connection; it can be a direct connection or an indirect connection through an intermediate medium, it can be the internal connection of two elements or the interaction relationship between two elements, unless otherwise clearly defined. For those skilled in the art, the specific meanings of the above terms in the present disclosure can be understood according to the specific circumstances.

In the present disclosure, when an element is referred to as being “fixed to” or “disposed on” another element, it may be directly on the other element or there may be an intermediate element. When an element is considered to be “connected to” another element, it may be directly connected to the other element or there may be an intermediate element at the same time. If present, the terms “vertical”, “horizontal”, “upper”, “lower”, “left”, “right” and similar expressions are for illustrative purposes only and are not intended to be the only embodiment.

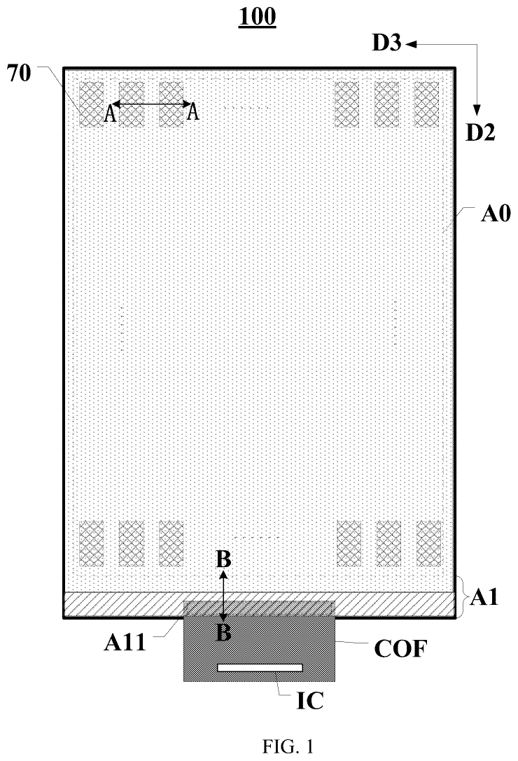

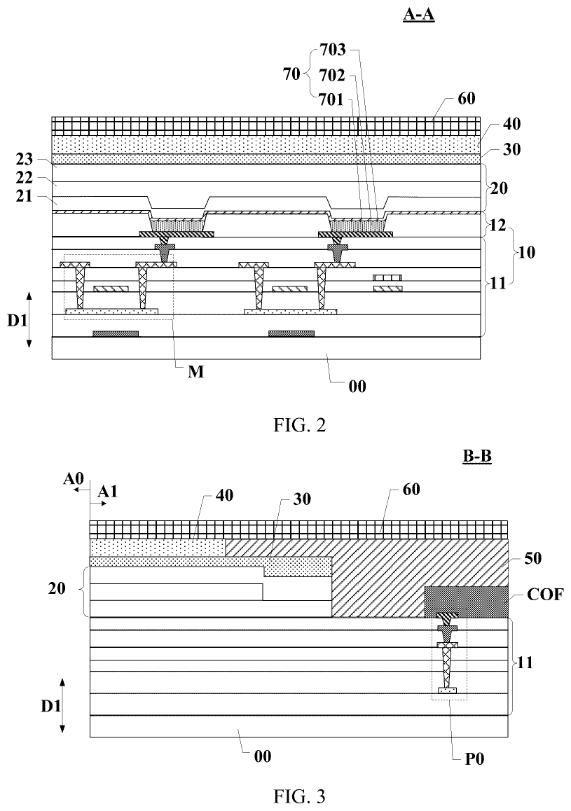

FIG. 1 is a top view of a display panel provided in an embodiment of the present disclosure, FIG. 2 is a cross-sectional view of the display panel in FIG. 1 taken along the AA direction, and FIG. 3 is a cross-sectional view of the display panel in FIG. 1 taken along the BB direction. It should be noted that FIG. 1 only uses a display panel with a rectangular structure as an example for illustration and does not limit the actual shape of the display panel. In some other embodiments of the present disclosure, the display panel may also be in any other feasible shape such as a circle or a rounded rectangle. The embodiment of FIG. 1 illustrates light-emitting elements in the display panel, but does not limit the actual number, shape, and arrangement of the light-emitting elements.

As shown in FIG. 1, FIG. 2, and FIG. 3, where FIG. 2 schematically illustrates a partial film layer structure of a display area A0 in the display panel and FIG. 3 schematically illustrates a partial film layer structure of a non-display area A1 in the display panel, one embodiment of the present disclosure provides a display panel 100, and the display panel 100 may include a substrate 00, and a display function layer 10, a first insulating layer 20, a second insulating layer 30 and a polarizer 40 arranged on one same side of the substrate 00. Along a first direction D1, the first insulating layer 20 may be disposed on a side of the display function layer 10 away from the substrate 00, the second insulating layer 30 may be disposed on a side of the first insulating layer 20 away from the substrate 00, and the polarizer 40 may be disposed on a side of the second insulating layer 30 away from the substrate 00. The first direction D1 may be perpendicular to the plane where the substrate 00 is located. Optionally, the display function layer 10 may include a driving layer 11 and a light-emitting element layer 12. The driving layer 11 may include transistors M, and the light-emitting element layer 12 may include a plurality of light-emitting elements 70. The first insulating layer 20 may be an encapsulation layer for encapsulating the plurality of light-emitting elements 70 to prevent external moisture, oxygen, or other impurities from affecting the characteristics of the display panel. Optionally, the aforementioned encapsulation layer may include a first inorganic layer 21, an organic layer 22, and a second inorganic layer 23 which are stacked. In the first non-display area A1, a cut-off position of the organic layer 22 may be further away from the bonding area A11 than cut-off positions of the first inorganic layer 21 and the second inorganic layer 23. In an area near the binding area A11, the first inorganic layer 21 and the second inorganic layer 23 may be in direct contact. In some other embodiments of the present disclosure, the first insulating layer 20 may also be any other suitable film layer. For example, when the display panel includes a touch layer, the touch layer may include two touch metal layers, and the first insulating layer 20 may be an insulating film layer for isolating the aforementioned two touch metal layers. The second insulating layer 30 and the polarizer 40 may be disposed on the side of the first insulating layer 20 away from the substrate 00. The second insulating layer 30 may be, for example, an organic planar layer. When a touch layer is provided in the display area of the display panel, the second insulating layer 30 may be used to cover the top of the touch layer, and a planarization film layer may be formed on the side of the touch layer away from the substrate.

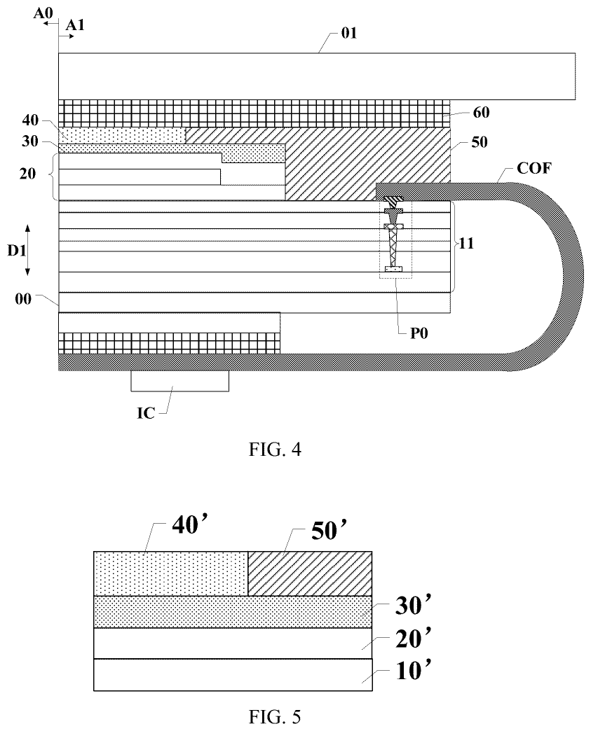

As shown in FIG. 1 and FIG. 3, the display panel 100 may include a display area A0 and a first non-display area A1 located on one side of the display area A0 along the second direction D2. The first non-display area A1 may include the binding area A11. The binding area A11 may be provided with binding pads P0. FIG. 3 only illustrates one composition of the binding pads and does not limit the actual film layer structure of the binding pads P0. The binding area A11 may be used to bind the chip-on-chip film COF, and control chips IC may be located on the chip-on-chip film COF. It should be noted that FIG. 1 only illustrates the situation where the chip-on-chip film COF is not been bent. In actual products, the chip-on-chip film COF may be bent toward one side of the substrate 00 facing away from the light-emitting surface of the display panel. For example, as shown in FIG. 4 which is a schematic diagram of a film layer after the chip-on-chip film COF is bent, one end of the chip-on-chip film 60 may be bound to one corresponding binding pad P0, and the other end may be bent to the side of the substrate 00 facing away from the light-emitting surface of the display panel. The control chips IC may be located on the chip-on-chip film 60. When the chip-on-chip film 60 is bound to the binding pads P0, the binding pads P0 may be able to be electrically connected to the control chips IC through the chip-on-chip film 60. After the chip-on-chip film 60 is bent to the side of the substrate 00 facing away from the light-emitting surface of the display panel, the control chips IC may be also bent to the side of the substrate 00 facing away from the light-emitting surface of the display panel.

As shown in FIG. 1, FIG. 3 and FIG. 4, a polarizer 40 may be disposed in the display area A0 and at least a portion of the first non-display area A1. The second insulating layer 30 and the first insulating layer 20 may be located in the display area A0 and at least a portion of the first non-display area A1. Along the first direction D1, the polarizer 40, the second insulating layer 30, and the first insulating layer 20 may not overlap with the binding area A11. In other words, the polarizer 40 may cover the entire display area A0 and extend to at least a portion of the first non-display area A1, but may not extend to the top of the binding area A11 to avoid interference with the binding area A11. In addition to covering the display area A0, the second insulating layer 30 and the first insulating layer 20 may also extend to the first non-display area A1, and may not extend to the top of the binding area A11. Optionally, the extension of the second insulating layer 30 and the first insulating layer 20 to the first non-display area A1 may be larger than the extension of the polarizer 40 to the first non-display area A1. That is, the ends of the second insulating layer 30 and the first insulating layer 20 in the first non-display area A1 may exceed the ends of the polarizer 40 in the first non-display area A1, and the ends of the second insulating layer 30 and the first insulating layer 20 may be closer to the binding area A11 than the ends of the polarizer 40.

As shown in FIG. 3, in one embodiment, the display panel may further include a first protective layer 50 and a second protective layer 60. The first protective layer 50 may be located in the first non-display area A1. Along the first direction D1, the first protective layer 50 may be at least located on the side of the second insulating layer 30 away from the substrate 00. Optionally, an end face of the polarizer 40 facing the binding area A11 may be connected to an end face of the first protective layer 50 facing the display area A0. Optionally, the first protective layer 50 may be a UV glue. After the COF is bound to the binding area A11 of the display panel, the first protective layer 50 may be used to cover the COF of the binding area A11, and fix the COF. Optionally, the second protective layer 60 may be an optically transparent glue. The second protective layer 60 may be located on the side of the polarizer 40 away from the substrate 00 and cover the polarizer 40. Along the first direction D1, the second protective layer 60 may overlap with the polarizer 40 and at least a part of the second protective layer 60. The second protective layer 60 may be used for the bonding of a cover plate and the display panel, for example, as shown in FIG. 4.

Optionally, in one embodiment, the display panel may be a display panel using organic light-emitting diode display technology, i.e., an OLED (Organic Light-Emitting Diode) display panel. FIG. 2 illustrates a connection relationship of the plurality of light-emitting elements 70 in the display area A0. As shown in FIG. 1 and FIG. 2, a basic structure of one light-emitting element 70 of the OLED display panel may include an anode 701, a light-emitting material layer 702, and a cathode 703. When the power supply supplies an appropriate voltage, holes generated by the anode 701 and electrons generated by the cathode 703 may combine in the light-emitting material layer 702 to generate bright light. The anode 701 of the light-emitting element may be electrically connected to the array layer 11, and the array layer 11 and the plurality of light-emitting elements 70 as a whole may form the display function layer 10. Compared with liquid crystal displays, OLED display panels may have the characteristics of high visibility and high brightness, and may be more power-saving, light in weight, and thin in thickness. Of course, in some other embodiments of the present disclosure, the display panel may also be a display panel using inorganic light-emitting diode display technology, such as a Micro LED display panel, or a Mini LED display panel, etc., and the present disclosure is not limited thereto.

In one embodiment of the present disclosure, the second insulating layer 30 and the first insulating layer 20 may not cover the binding area A11. Therefore, there may be a height difference between the binding area A11 and the first non-display area A1 on the side of the binding area A11 facing the display area A0. When the first protective layer 50 is introduced into the first non-display area A1, the first protective layer 50 may not only fix the COF bound to the binding area A11, but also compensate for the above-mentioned height difference. In one optional embodiment of the present disclosure, the plane of the side of the first protective layer 50 away from the substrate 00 and the plane of the side of the polarizer 40 away from the substrate 00 may be located in the same plane.

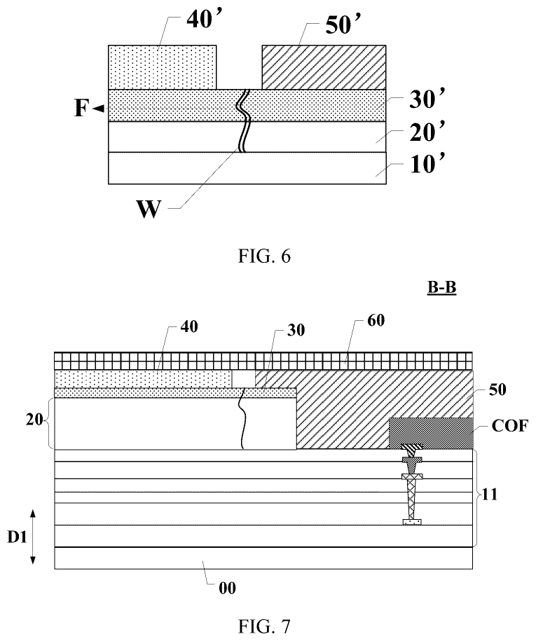

For display products, reliability tests are usually performed before leaving the factory. FIG. 5 shows a schematic diagram of film layers of a display panel in the related art before the reliability test, and FIG. 6 shows a schematic diagram of film layers of a display panel in the related art after the reliability test. The display panel includes an array layer 10′, a first insulating layer 20′, a second insulating layer 30′ and a polarizer 40′, stacked. An end of the polarizer 40′ is in contact with the protective adhesive layer 50′. During the reliability test before the product leaves the factory, because of its material properties, the polarizer 40′ will shrink, forming a shrinkage stress and causing the polarizer 40′ to separate from the protective adhesive layer 50′. The shrinkage stress generated by the polarizer 40′ causes the second insulating layer 30′ and the packaging layer 20′ below the polarizer 40′ to rupture and form a crack W. External water vapor penetrates the cracks in the second insulating layer 30′ and the packaging layer 20′ and invades the array layer 10′, causing corrosion to the metal film layer in the array layer 10′, affecting the performance reliability of the product and causing the test failure.

To solve the above technical problems, in the display panel provided by the present disclosure, as shown in FIG. 1 and FIG. 3, the second protective layer 60 may be introduced on the side of the polarizer 40 away from the substrate 00, and the second protective layer 60 may cover the polarizer 40. That is, along the first direction D1, the orthographic projection of the second protective layer 60 on the substrate 00 may cover the orthographic projection of the polarizer 40 on the substrate 00. Along the first direction D1, the second protective layer 60 may also overlap with at least part of the first protective layer 50, which is equivalent to the second protective layer 60 further extending in the direction of the binding area A11 and covering at least part of the first protective layer 50. That is, the second protective layer 60 may be in direct contact with the first protective layer 50. Therefore, during the reliability test, when the polarizer 40 shrinks because of the characteristics of its material, the second protective layer 60 and the first protective layer 50 may be in direct contact and mutually pulled, such that the second protective layer 60 does not shrink with the shrinkage of the polarizer 40 and may still cover the area between the polarizer 40 and the first protective layer 50. For example, as shown in FIG. 7, which shows a schematic diagram of film layers of the display panel in the embodiment of the present disclosure after the reliability test, the second protective layer 60 may isolate external moisture and impurities. Even when the second insulating layer 30 and the first insulating layer 20 are affected by the shrinkage stress of the polarizer 40 and cracks are generated, the external moisture and impurities may not be able to enter the above cracks through the second protective layer 60, which is conducive to improving the overall packaging reliability of the display panel, and further to improve the performance stability of the display panel.

It should be noted that the embodiment shown in FIG. 3 shows a solution in which the second protective layer 60 fully covers the first protective layer 50, as an example only, and the present disclosure is not limited to this. In some other embodiments of the present disclosure, the second protective layer 60 may also cover at least part of the area of the first protective layer 50.

Optionally, in one embodiment, the first protective layer 50 and the second protective layer 60 mentioned may both be adhesive layers. The first protective layer 50 may be made of, for example, transparent optical adhesive, and the second protective layer 60 may be made of, for example, ultraviolet curing adhesive. Both are adhesive materials. When the two are in direct contact, a large contact force may be generated, which is conducive to resisting the influence of the shrinkage stress of the polarizer 40. Even when the polarizer 40 shrinks, the relative position between the first protective layer 50 and the second protective layer 60 may not or almost not change.

As shown in FIG. 2 and FIG. 3, in an optional embodiment of the present disclosure, the substrate 00 may be a rigid substrate. When the substrate 00 is a rigid substrate, its stability may be relatively strong. In the reliability test of the display panel, the rigid substrate 00 may not be affected by the shrinkage stress of the polarizer 40, thereby playing a reliable fixing role for the display function layer 10 above the substrate 00, avoiding abnormal problems such as film breakage caused by the shrinkage of the polarizer 40 in the display function layer 10 and other structures. Since the aforementioned second insulating layer 30 and the first insulating layer 20 may be located between the polarizer 40 and the display function layer 10, considering the characteristics of the materials of the second insulating layer 30 and the first insulating layer 20 themselves, they may be affected by the shrinkage stress of the polarizer 40. However, since the second protective layer 60 located on the side of the polarizer 40 away from the substrate 00 may be in direct contact with the first protective layer 50, the contact force between the two may resist the influence of the shrinkage stress of the polarizer 40. Therefore, when the second insulating layer 30 or the first insulating layer 20 cracks because of the shrinkage stress of the polarizer 40, the second protective layer 60 may still play a role in isolating water and oxygen, which may be conducive to ensuring the performance stability of the display product.

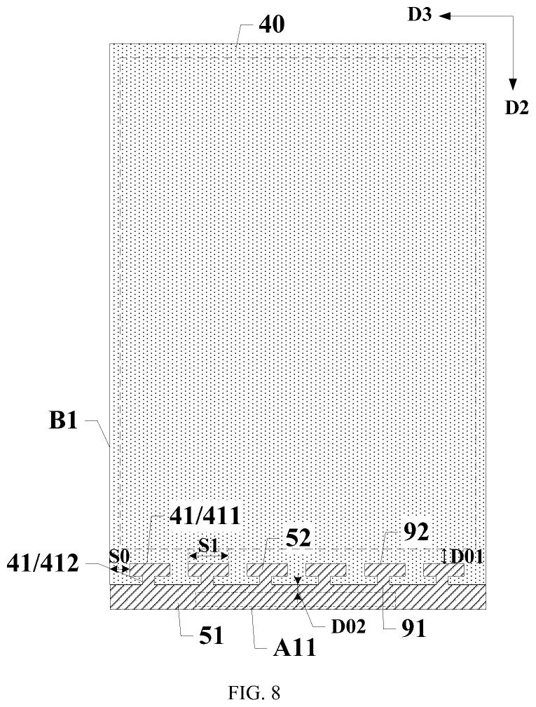

FIG. 8 is a top view of the polarizer 40 and the first protective layer 50 provided in one embodiment of the present disclosure. As shown in FIG. 8, in an optional embodiment of the present disclosure, the first protective layer 50 may include a main body 51 and protrusions 52 connected to the main body 51. The protrusion 52 may be located on a side of the main body 51 facing the display area A0. The polarizer 40 may include limit grooves 41, and the limit grooves 41 may be located at an end of the polarizer 40 facing the binding area A11. One protrusion 52 may be located in one corresponding limit groove 41.

Compared with the solution in which the ends of the polarizer 40 and the first protective layer 50 are connected and flush in the embodiment shown in FIG. 1, in this embodiment, the limit groove 41 may be disposed at the end of the polarizer 40 facing the binding area A11. The limit groove 41 may be regarded as a structure formed by recessing a part of the end surface of the polarizer 40 facing the binding area A11 along the direction from the binding area A11 to the display area A0. When forming the first protective layer 50, the first protective layer 50 may form a protrusion 52 filled in the above-mentioned limit groove 41. The protrusion 52 may be in direct contact with the limit groove 41, and the protrusion 52 may have a pulling effect on the polarizer 40 through the limit groove 41. During the reliability test, the pulling effect may be conducive to suppressing the polarizer 40 from shrinking in the direction away from the binding area A11. When the polarizer 40 does not shrink or the shrinkage range is small, its shrinkage stress may be small, and the shrinkage stress may also have a small impact on the second insulating layer 30 and the first insulating layer 20 located on the side of the polarizer 40 facing the substrate 00, thereby helping to avoid the problem of cracks in the second insulating layer 30 and the first insulating layer 20 because of the influence of large shrinkage stress. Therefore, introducing the limit groove 41 on the polarizer 40 and the protrusion 52 on the first protective layer 50 may be conducive to further improving the packaging reliability of the display product, and then to further improve the performance stability of the display product.

It should be noted that the inner contour shape of the limit groove 41 on the polarizer 40 in the disclosed embodiment matches the outer contour shape of the protrusion 52 on the first protective layer 50.

Optionally, the first protective layer 50 may be a UV curing adhesive. Before curing, the first protective layer 50 may be in a flowing state, which may be conducive to filling the limit groove 41 on the polarizer 40. Subsequently, UV curing may be performed, which may be conducive to increasing the contact area between the protrusion 52 on the first protective layer 50 and the limit groove 41 on the polarizer 40, thereby facilitating the improvement of the traction between the two.

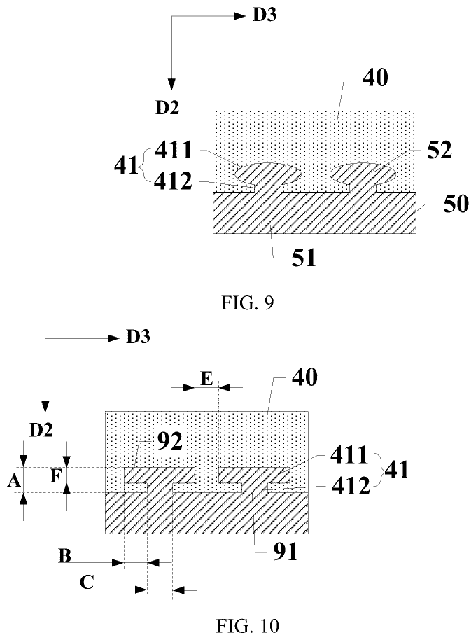

FIG. 9 and FIG. 10 are respectively partial schematic diagrams of the polarizer 40 provided in the embodiments of the present disclosure, which specifically show the structure of the limit groove 41 on the polarizer 40. As shown in FIG. 1, FIG. 8, FIG. 9 and FIG. 10, in an optional embodiment of the present disclosure, the limit groove 41 may include a first portion 411 and a second portion 412 arranged along a second direction D2, and the second portion 412 may be located between the first portion 411 and the binding area A11. Along a third direction D3, the maximum width of the first portion 411 may be larger than the maximum width of the second portion 412, and the third direction D3 may be parallel to the plane where the substrate 00 is located and perpendicular to the second direction D2.

The embodiment shown in FIG. 9 may be described by taking the plane outline of the first portion 411 as an ellipse and the plane outline of the second portion 412 as a rectangle as an example, and the embodiment shown in FIG. 10 may be described by taking the plane outlines of the first portion 411 and the second portion 412 as rectangles as an example, for illustration purposes only. The present disclosure is not limited to this. As shown in FIG. 9 and FIG. 10, the first portion 411 and the second portion 412 in the limit groove 41 may be interconnected. The second portion 412 may be closer to the binding area A11 than the first portion 411. In this embodiment, the maximum width of the second portion 412 which is closer to the binding area may be set to be smaller than the maximum width of the first portion 411 which is farther from the binding area A11. When the protrusion 52 of the first protective layer 50 is located in the limit groove 41 of this shape, the protrusion 52 and the limit groove 41 may form a barb-like structure. When the display product is used in a reliability test or in an environment similar to a reliability test (such as a high temperature and high humidity environment), the traction force of the protrusion 52 on the limit groove 41 may be larger, and the protrusion 52 may be less likely to detach from the limit groove 41, which may be more conducive to suppressing the shrinkage of the polarizer 40 and reducing the influence of the shrinkage stress on the second insulating layer 30 and the first insulating layer 20.

It should be noted that the embodiments of FIG. 9 and FIG. 10 only illustrate the shapes of the first portion 411 and the second portion 412 of the limit groove 41, as examples, and do not limit the scope of the present disclosure. In some other embodiments of the present disclosure, the first portion 411 and the second portion 412 may also be embodied in any other feasible shapes, provided that the maximum width of the first portion 411 is larger than the maximum width of the second portion 412. For example, when the plane contour of the first portion 411 is a circle or a rectangle, the plane contour of the second portion 412 may also be a circle or an ellipse with a smaller diameter, or an inverted trapezoid with a smaller maximum width.

In an optional embodiment of the present disclosure, as shown in FIG. 10, in the limit groove 41 of the polarizer 40, the orthographic projections of the first portion 411 and the second portion 412 on the plane where the substrate 00 is located may be both rectangular. Along the second direction D2, the depth of the first portion 411 may be F, and the total depth of the limit groove 41 may be A, where F:A≥3:5.

When the contour shapes of the first portion 411 and the second portion 412 in the limit groove 41 of the polarizer 40 are both rectangular, it may be beneficial to simplify the difficulty of forming the limit groove 41 on the polarizer 40 and improve production efficiency. At this time, the first portion 411 may be embodied as a long rectangular structure as shown in FIG. 10. The extension direction of its long side may be the arrangement direction of different limit grooves 41, and the extension direction of its short side may be the arrangement direction of the display area A0 and the binding area A11. The second portion 412 may be embodied as a rectangular structure connected to the first portion 411 and having a width less than the length of the long side of the first portion 411. The first portion 411 and the second portion 412 may be embodied as a T-shaped structure as a whole. The present embodiment further defines that the relationship between the depth of the first portion 411 along the second direction D2 and the total depth of the limit groove 41 satisfies F:A≥3:5, such that in the entire limit groove 41, the depth of the first portion 411 accounts for a relatively large proportion, and the depth of the first portion 411 may be larger than the depth of the second portion 412. In this way, when the display panel is used in a reliability test or in an environment similar to a reliability test, the mutual traction between the protrusion 52 in the first protective layer 50 and the limit groove 41 in the polarizer 40 may be larger, which may be more conducive to suppressing the shrinkage of the polarizer 40, thereby being more conducive to reducing the influence of the shrinkage force of the polarizer 40 on the second insulating layer 30 and the first insulating layer 20 to ensure the packaging reliability of the first insulating layer 20 for the display panel.

As shown in FIG. 8, in an optional embodiment of the present disclosure, the polarizer 40 may include a plurality of limit grooves 41 arranged along a third direction D3, where the third direction D3 is parallel to the plane where the substrate 00 is located and perpendicular to the second direction D2. Along the third direction D3, the maximum width of one single limit groove 41 may be S1, and the minimum distance between the first edge B1 of the polarizer 40 and one limit groove 41 adjacent to the first edge 91 may be S0, where S0≤S1 and the first edge 91 extends along the second direction D2.

In the present embodiment of the present disclosure, the plurality of limit grooves 41 may be introduced to cooperate with the first protective layer 50 at the end of the polarizer 40. When the number of the plurality of limit grooves 41 is larger, the mutual traction between the limit grooves 41 and the protrusions 52 on the first protective layer 50 may be larger, which may be more conducive to suppressing the shrinkage of the polarizer 40.

In this embodiment, the minimum distance between the limiting groove 41 adjacent to the first edge 91 of the polarizer 40 and the first edge 91 is described. The minimum distance S0 may be regarded as the distance between the first portion 411 in the limiting groove 41 and the first edge 91. The maximum width S1 of one single limiting groove 41 may be regarded as the width of the first portion 411 in the limiting groove 41 along the third direction D3. When the relationship between the minimum distance and the maximum width is defined as S0≤S1 in this embodiment, it may be equivalent to that there is not enough space between the first edge 91 of the polarizer 40 and the limiting groove 41 adjacent thereto to set another limiting groove 41 and ensure that there is a gap between adjacent limiting grooves 41. That is, limiting grooves 41 of the plurality of limiting grooves 41 located in the edge area may be set as close to the first edge 91 of the polarizer 40 as possible, which is conducive to increasing the traction force between the limiting grooves 41 and the protrusion 52 that the edge area of the polarizer 40 may be subjected to, thereby facilitating the avoidance of the phenomenon that the area of the polarizer 40 close to its first edge 91 shrinks inward.

Optionally, the plurality of limiting grooves 41 may be evenly arranged at the end of the polarizer 40 facing the binding area A11, such that the edge of the polarizer 40 provided with the limiting grooves 41 is more evenly subjected to the traction force of the protrusion 52, thereby avoiding the problem of local shrinkage of the area when the area at the end of the polarizer 40 where the limiting grooves 41 are not provided is large. When the plurality of limiting grooves 41 are evenly arranged at the end of the polarizer 40 and the distance between the limiting groove 41 adjacent to the first edge 91 and the first edge 91 is less than the maximum width of the limiting groove 41, the end of the polarizer 40 facing the binding area A11 may be more evenly subjected to the traction of the protrusion 52 in the first protective layer 50, which is beneficial to improving the uniformity of the force on the end of the polarizer 40 as a whole and avoiding the problem of local shrinkage.

As shown in FIG. 8 and FIG. 10, in an optional embodiment of the present disclosure, the limiting portion may include a plurality of limiting grooves 41 arranged along a third direction D3, where the third direction D3 is parallel to the plane where the substrate 00 is located and is perpendicular to the second direction D2. Along the second direction D2, the depth of one limiting groove 41 may be A. Along the third direction D3, the minimum spacing width between two adjacent limiting grooves 41 may be E. One limiting groove 41 may include a first opening 91, the first opening 91 may be located on the side wall of the polarizer 40 facing the binding area A11, and along the third direction D3, the width of the first opening 91 may be C. In one embodiment, A=E=C. It should be noted that the minimum spacing width E between adjacent limiting grooves 41 mentioned in this embodiment may be the spacing width between two first portions 411 of the adjacent limiting grooves 41. The first opening 91 of the limiting groove 41 may be a mouth of the limiting groove 41 facing the binding area A11. In this embodiment, the depth A of the limit groove 41, the minimum spacing width E between adjacent limit grooves 41, and the width C of the first opening 91 may be designed to be equal in size, such that the traction force on the area of the polarizer 40 where the plurality of limit grooves 41 may be set and the area between adjacent limit grooves 41 may be as consistent as possible to avoid the problem of local shrinkage caused by uneven force on the end of the polarizer 40. Optionally, in this embodiment, the limit grooves 41 set at the end of the polarizer 40 may be arranged at equal distances at the end of the polarizer 40, and the minimum spacing between the limit grooves 41 adjacent to the first edge 91 of the polarizer 40 and the first edge 91 may be smaller than the spacing of the limit grooves 41, which may be more conducive to improving the force uniformity of different areas at the end of the polarizer 40.

As shown in FIG. 8 and FIG. 10, in an optional embodiment of the present disclosure, the limiting groove 41 may also include a first groove bottom 92 arranged opposite to the first opening 91 along the second direction D2. Along the third direction D3, the minimum distance between the edge of the first groove bottom 92 and the edge of the first opening 91 may be B, and the width of the first opening 91 may be C, where B=C.

In the present disclosure, along the third direction D3, the width of the first portion 411 of the limiting groove 41 may be larger than the width of the second portion 412. Optionally, the center lines of the first portion 411 and the second portion 412 along the second direction D2 may coincide. In this embodiment, the minimum distance between the edge of the first groove bottom 92 and the edge of the first opening 91 may be B, which may be regarded as the width of the portion of the first portion 411 that exceeds the first opening 91 on the same side of the first opening 91 along the third direction D3. In this embodiment, the width may be set equal to the width C of the first opening 91. In this way, after the protrusion 52 of the first protective layer 50 is matched with the limiting groove 41 of the polarizer 40, it may be beneficial to balance the uniformity of the traction force of the area where the first portion 411 may be set and the area where the second portion 412 may be set, thereby facilitating the improvement of the force consistency of different areas on the polarizer 40.

As shown in FIG. 8, in an optional embodiment of the present disclosure, the limiting groove 41 may include a first opening 91 located on the side wall of the polarizer 40 facing the binding area A11, and the limiting groove 41 may also include a first groove bottom 92 arranged opposite to the first opening 91 along the second direction D2. Along the second direction D2, the distance between the first groove bottom 92 and the display area A0 may be D01, where D01≥0.5 mm. That is, when the limiting groove 41 is introduced into the polarizer 40, the spacing between the limiting groove 41 and the display area A0 may be at least 0.5 mm. This may be beneficial to avoid the introduction of the limiting groove 41 from affecting the wide-angle light output in the display area A0, and may be beneficial to ensuring the display effect after the limiting groove 41 may be introduced into the polarizer 40.

Optionally, in one embodiment, the end face of the polarizer 40 facing the binding area A11 may be at a distance D02 from the binding area A11, and D02≥0.2 mm. That is, the polarizer 40 may be at least 0.2 mm away from the binding area A11. When the limiting groove 41 is introduced into the polarizer 40, the distance between the end face where the first opening 91 of the limiting groove 41 is located and the binding area A11 may be D02. This arrangement may allow a certain distance between the polarizer 40 and the first binding area A11, and a certain attachment deviation range may be reserved to prevent the attached polarizer 40 from interfering with the binding area A11.

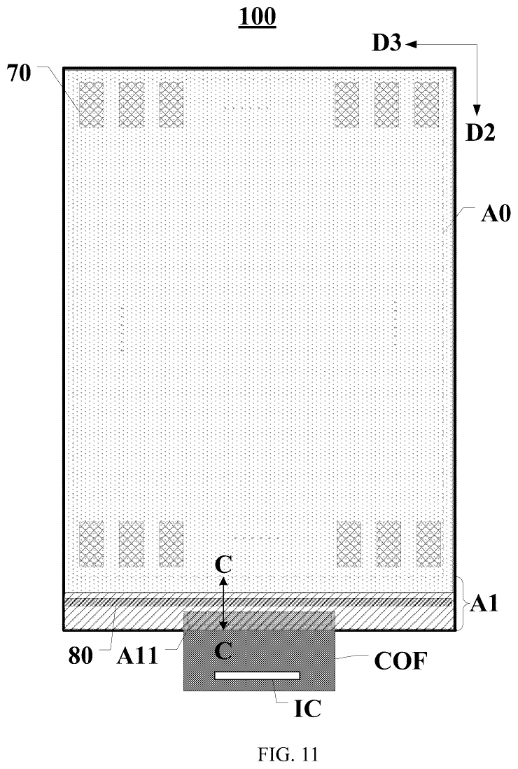

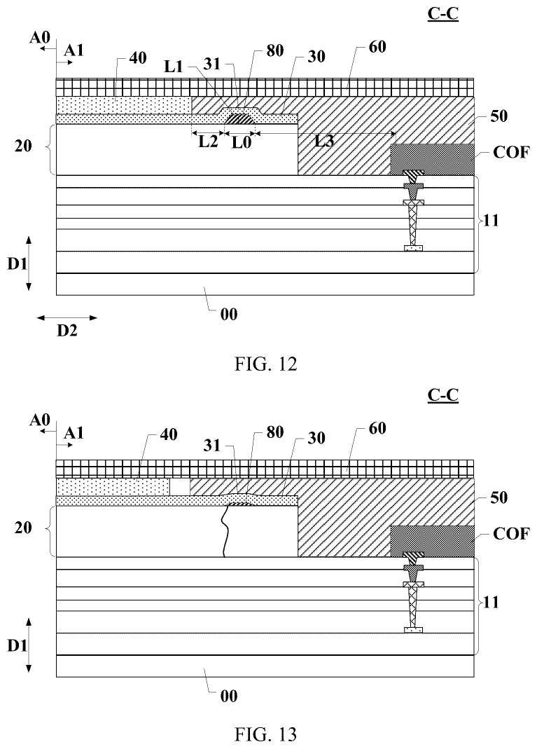

In another embodiment, as shown in FIG. 11 which is another top view of the display panel provided by an embodiment of the present disclosure and FIG. 12 which shows a cross-sectional view of the display panel along the CC direction in FIG. 11, the display panel may also include an elastic pad 80 located in the first non-display area A1, and the elastic pad 80 may extend along the third direction D3. The third direction D3 may be parallel to the plane where the substrate 00 is located and perpendicular to the second direction D2. In the first non-display area A1, the elastic pad 80 may be located between the first insulating layer 20 and the second insulating layer 30. The second insulating layer 30 may include a convex portion 31, and along the first direction D1, the convex portion 31 may overlap with the elastic pad 80. The distance between the convex portion 31 and the substrate 00 may be larger than the distance between the second insulating layer 30 and the substrate 00 in the display area A0.

As shown in FIG. 11 and FIG. 12, in this embodiment, the elastic pad 80 may be disposed between the second insulating layer 30 and the first insulating layer 20 in the first non-display area A1. The elastic pad 80 may have a certain elasticity. The second insulating layer 30 may cover the side of the elastic pad 80 away from the substrate 00. A convex portion 31 may be formed at a position corresponding to the elastic pad 80. A side of the convex portion 31 facing the substrate 00 may be supported by the aforementioned elastic pad 80, such that the distance between the surface of the convex portion 31 away from the substrate 00 and the substrate 00 may be larger than the distance between the surface of the second insulating layer 30 in the display area A0 away from the substrate 00 and the substrate 00. When the display panel is used in a reliability test or in an environment similar to a reliability test, the second insulating layer 30 may shrink in the direction of the display area A0 because of the shrinkage stress of the polarizer 40 when the polarizer 40 shrinks. At this time, since the elastic pad 80 may be introduced between the second insulating layer 30 and the first insulating layer 20, the elastic pad 80 may be stretched under the shrinkage of the second insulating layer 30, and the convex portion 31 of the second insulating layer 30 may also be stretched, forming a structure such as shown in FIG. 13. Since the elastic pad 80 may be introduced, it may be equivalent to reserving a certain amount of displacement for the shrinkage of the second insulating layer 30, which may be conducive to avoiding the problem of cracks in the second insulating layer 30 because of the shrinkage stress of the polarizer 40. FIG. 13 shows a schematic diagram of the film layers of the display panel when the polarizer 40 shrinks. At this time, even when the first insulating layer 20 may be cracked because of the shrinkage stress of the polarizer 40, since the second insulating layer 30 arranged above it has no cracks, it may prevent external water oxygen or impurities from entering the display function layer 10 through the cracks of the first insulating layer 20. Further, in this embodiment, the second protective layer 60 may be disposed on the side of the polarizer 40 away from the substrate 00. While the second protective layer 60 covers the polarizer 40, it may be also in direct contact with the first protective layer 50 in the first non-display area A1. Even when the polarizer 40 shrinks, the first protective layer 50 and the second protective layer 60 may still be reliably combined, and the first protective layer 50 may also isolate the display panel from external water vapor and impurities. Therefore, the double-layer effect of the first protective layer 50 and the second insulating layer 30 may effectively avoid the influence of external water vapor and impurities on the display panel, which may be conducive to improving the overall packaging reliability of the display panel and further conducive to improving the performance reliability of the display panel.

As shown in FIG. 12, in an optional embodiment of the present disclosure, the shape of the first cross section of the elastic pad 80 may be an arc or a trapezoid, and the first cross section may be perpendicular to the plane where the substrate 00 is located and parallel to the second direction D2. The embodiment shown in FIG. 12 where the cross section of the elastic pad 80 is a trapezoid is used as an example for description purposes only, and the present disclosure may be not limited to this. In some other embodiments of the present disclosure, the cross section of the elastic pad 80 may also be embodied as other feasible structures such as an arc. For example, it may be embodied as any other feasible structure with a narrow top and a wide bottom.

As shown in FIG. 12 and FIG. 13, in an optional embodiment of the present disclosure, the elastic pad 80 may have an initial state and a stretched state. In the initial state, the height of the elastic pad 80 may be larger than the height of the elastic pad 80 in the stretched state. FIG. 12 may be embodied as the initial state, that is, the state in which the polarizer 40 has not yet shrunk, and FIG. 13 may be embodied as the stretched state, that is, the state in which the polarizer 40 has shrunk. In the initial state, the maximum width of the first cross section of the elastic pad 80 along the second direction D2 may be 0, and L0≥0.1 mm. Since the amount of shrinkage of the polarizer 40 in the display panel during reliability testing or when the display panel may be used in an environment similar to reliability testing may be usually less than 0.1 mm, when the maximum width of the elastic pad 80 in the initial state is set to be larger than or equal to 0.1 mm, sufficient stretching space may be reserved for the second insulating layer 30 to be stretched by the shrinkage stress of the polarizer 40 without generating cracks, which may be beneficial to ensure the coverage reliability of the second insulating layer 30 on the first insulating layer 20, and further beneficial to improving the overall packaging reliability of the display panel.

Optionally, as shown in FIG. 13, in the initial state, the height of the first section of the elastic pad 80 along the first direction D1 may be L1, and L1≥0.05 mm. The height of the elastic pad 80 may also affect its stretching amount. In this embodiment of the present disclosure, when the height of the elastic pad 80 is set to be larger than or equal to 0.05 mm, it may be conducive to meeting the stretching amount requirement of the second insulating layer 30 when the polarizer 40 shrinks.

As shown in FIG. 12, in an optional embodiment of the present disclosure, along the second direction D2, the elastic pad 80 may be located between the polarizer 40 and the binding area A11. In the initial state, the minimum distance between the elastic pad 80 and the polarizer 40 may be L2, and the minimum distance between the elastic pad 80 and the binding area A11 may be L3, where L2≥0.2 mm and L3≥0.2 mm.

When the elastic pad 80 is introduced in the first non-display area A1 and between the second insulating layer 30 and the first insulating layer 20, the elastic pad 80 may need to be spaced a certain distance from both the display area A0 and the binding area A11. Considering that the shrinking amount of the polarizer 40 is less than about 0.1 mm when it shrinks, even when the elastic pad 80 is stretched because of the shrinking stress of the polarizer 40, its stretching amount may be less than 0.1 mm. Therefore, when the spacing distance between the elastic pad 80 and the display area A0 and the spacing distance between the elastic pad 80 and the binding area A11 are set to be larger than or equal to 0.2 mm, even after the elastic pad 80 is stretched, a certain spacing space may still be reserved between the display area A0 and the binding area A11, thereby avoiding the elastic pad 80 from affecting the display area A0 and the binding area A11, which is conducive to ensuring the performance stability of the display panel when the elastic pad 80 is introduced.

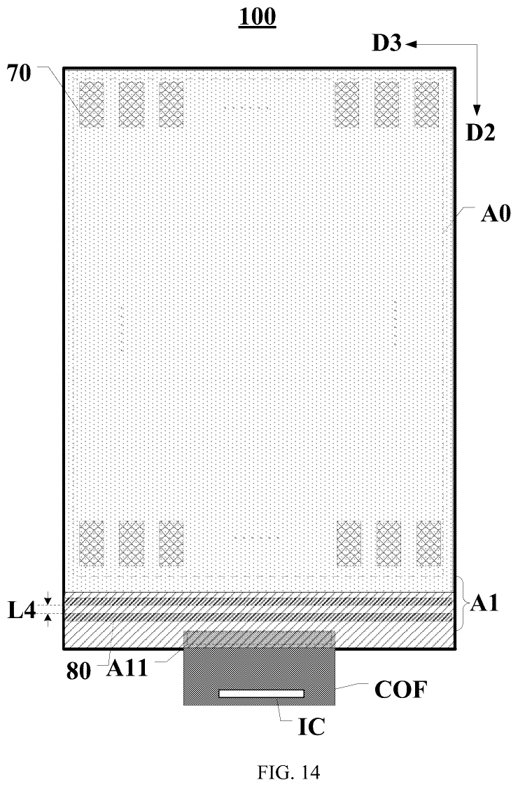

The above embodiments show the introduction of one elastic pad 80 in the first non-display area A1 as an example. In some other embodiments of the present disclosure, when the space in the first non-display area A1 is sufficient, two or more elastic pads 80 may be introduced into the first non-display area A1. For example, as shown in FIG. 14 which illustrates another top view of the display panel, in another optional embodiment of the present disclosure, the display panel may include at least two elastic pads 80 arranged along the second direction D2. In the initial state, the distance between adjacent elastic pads 80 along the second direction D2 may be L4, and L4≥0.1 mm.

When two elastic pads 80 are introduced into the first non-display area A1, the shape structures, sizes of the two elastic pads 80, and the distance of the two elastic pads 80 from the display area A0 and the binding area A11 may refer to the embodiments shown in FIG. 10 and FIG. 11, and the present disclosure may not repeat them. In the first non-display area A1, the second insulating layer 30 may cover the two elastic pads 80 to form two protrusions 31.

When two elastic pads 80 are introduced into the first non-display area A1, the second insulating layer 30 may form two protrusions 31 accordingly. When the polarizer 40 shrinks, the two elastic pads 80 may be stretched under the influence of the tensile stress of the second insulating layer 30. The two elastic pads 80 may provide the second insulating layer 30 with twice the stretching reserve, which may be more conducive to avoiding the problem of cracks in the second insulating layer 30 under the influence of the shrinkage stress of the polarizer 40.

As shown in FIG. 12, in an optional embodiment of the present disclosure, in the initial state, the height of the first section of the elastic pads 80 along the first direction D1 may be L1, and L1≥0.05mm. The height of the elastic pads 80 may also affect their stretching amount. In the embodiment of the present disclosure, when the height of the elastic pads 80 is set to be larger than or equal to 0.05 mm, it may be conducive to meeting the stretching amount requirement of the second insulating layer 30 when the polarizer 40 shrinks.

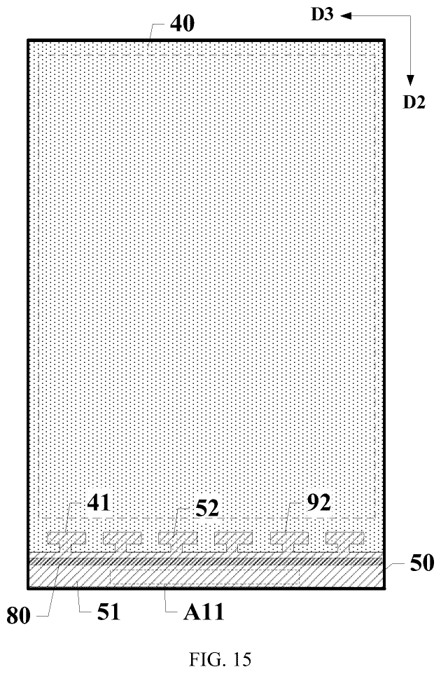

As shown in FIG. 15 which is another planar schematic diagram of the display panel, in one embodiment of the present disclosure, when the elastic pads 80 are introduced into the first non-display area A1, the end of the polarizer 40 facing the binding area A11 may also be provided with a limiting groove 41, and the protrusion 52 in the first protective layer 50 may also be embedded in the above-mentioned limiting groove 41. The contraction of the polarizer 40 may be limited by the mutual traction force between the limiting groove 41 and the protrusion 52. At the same time, the introduction of the elastic pads 80 may play an auxiliary role to prevent the second insulating layer 30 from being affected by the shrinkage stress and cracking when the polarizer 40 shrinks, which may be more conducive to improving the packaging reliability of the display panel.

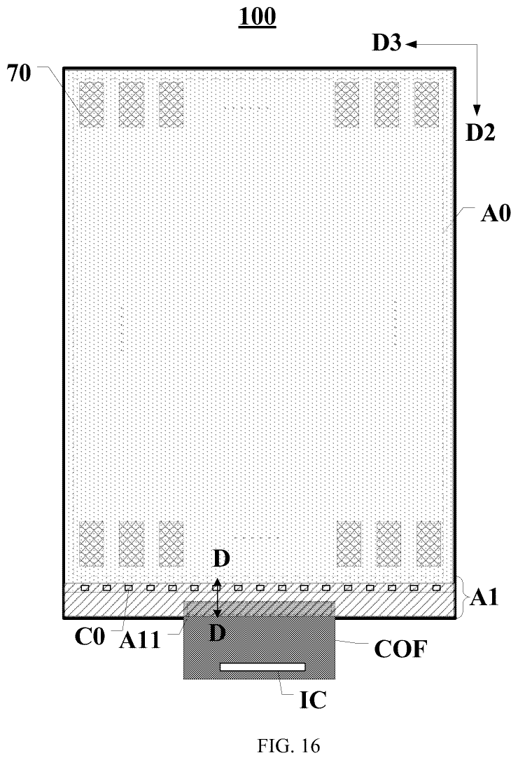

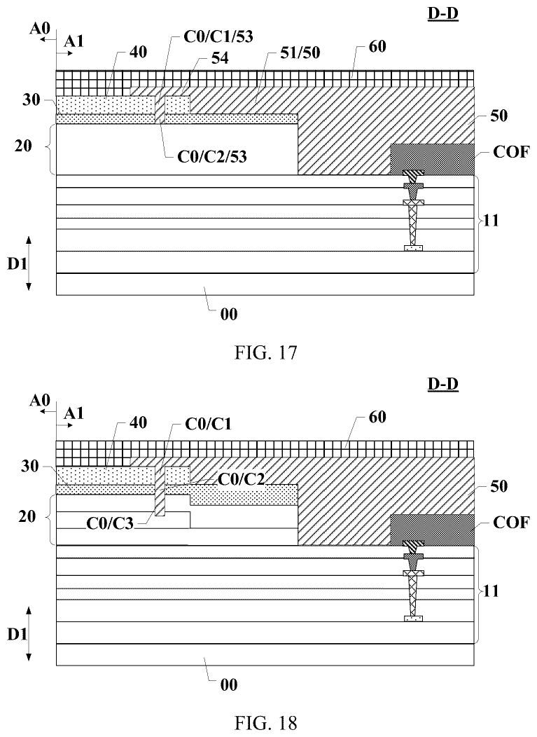

In another embodiment, as shown in FIG. 16 which is another top view of the structure of the display panel and FIG. 17 which is a DD-direction cross-sectional view of the display panel shown in FIG. 16, the display panel may also include at least one groove C0 located in the first non-display area A1. Along the first direction D1, the at least one groove C0 may at least penetrate the polarizer 40 and the second insulating layer 30. The first protective layer 50 may include a main body 51 and an extension portion 53 connected to the main body 51. The extension portion 53 may be at least located in the at least one groove C0.

In the embodiment shown in FIG. 16 and FIG. 17, the at least one connected groove C0 may be disposed in the first non-display area A1, at least on the polarizer 40 and the second insulating layer 30. When the first protective layer 50 is formed in the first non-display area A1, the at least one groove C0 may at least penetrate the polarizer 40 and the second insulating layer 30. In the top view structure, the at least one groove C0 may be evenly arranged in the first non-display area A1. In this embodiment, the surface of the first protective layer 50 facing away from the substrate 00 may be set higher than the surface of the polarizer 40 facing away from the substrate 00, such that at least part of the extension portion 53 in the first protective layer 50 is filled into the above-mentioned at least one groove C0. In this way, the main body 51 of the first protective layer 50 and the extension portion 53 located in the at least one groove C0 may form a hook shape as a whole. When the polarizer 40 shrinks, the hook-shaped first protective layer 50 may generate traction on the polarizer 40 and the second insulating layer 30, thereby suppressing the shrinkage of the polarizer 40, which is beneficial to avoid the problem of cracks in the second insulating layer 30 because of the shrinkage stress of the polarizer 40. It may be also beneficial to improve the packaging reliability of the display panel.

It should be noted that the embodiment shown in FIG. 17 shows a scheme in which the at least one groove C0 penetrates the polarizer 40 and the second insulating layer 30. In some other embodiments of the present disclosure, the at least one groove C0 may further penetrate at least part of the first insulating layer 20. For example, as shown in FIG. 18, which is another DD-direction cross-sectional view of the display panel in the embodiment of FIG. 16, when the at least one groove C0 penetrates the polarizer 40, the second insulating layer 30 and at least part of the first insulating layer 20, the depth of the at least one groove C0 may increase, and the coverage area of the first protective layer 50 in the at least one groove C0 may increase, which is more beneficial to improve the overall traction force of the first protective layer 50 on the polarizer 40 and is more beneficial to suppress the shrinkage of the polarizer 40.

In another embodiment, as shown in FIG. 17, the first protective layer 50 may also include a connecting portion 54 connecting the main body 51 and the extension portion 53, and at least part of the connecting portion 54 may be located on the side of the polarizer 40 away from the substrate 00. Along the first direction D1, the second protective layer 60 may cover the first protective layer 50.

In this embodiment, in addition to covering the binding area A11, the first protective layer 50 may also extend in the first non-display area A1 and on the side of the polarizer 40 away from the substrate 00 further toward the display area A0, and fill the aforementioned at least one groove C0. The connecting portion 54 used to connect the main body 51 and the extension portion 53 mentioned in this embodiment may be a portion of the first protective layer 50 located on the surface of the polarizer 40 away from the substrate 00. The hook shape formed by the main body 51, the connecting portion 54 and the extension portion 53 in the first protective layer 50 may play a traction role when the polarizer 40 shrinks. Therefore, it may be beneficial to suppress the shrinkage of the polarizer 40, and further help to avoid the problem of cracks in the second insulating layer 30 and the first insulating layer 20 because of the shrinkage stress of the polarizer 40.

In this embodiment, the second protective layer 60 may cover the first protective layer 50, which means that the surface of the first protective layer 50 facing away from the substrate 00 may be covered by the second protective layer 60. The second protective layer 60 may directly contact the first protective layer 50 to form a contact force. When the polarizer 40 shrinks, the contact stress between the first protective layer 50 and the second protective layer 60 may also reduce the shrinkage of the polarizer 40 to a certain extent. At the same time, the second protective layer 60 may fully cover the polarizer 40 and the surface of the second protective layer 60 facing away from the substrate 00, which may be also conducive to improving the overall packaging reliability of the display panel and avoiding the influence of external water, oxygen and impurities on the display panel.

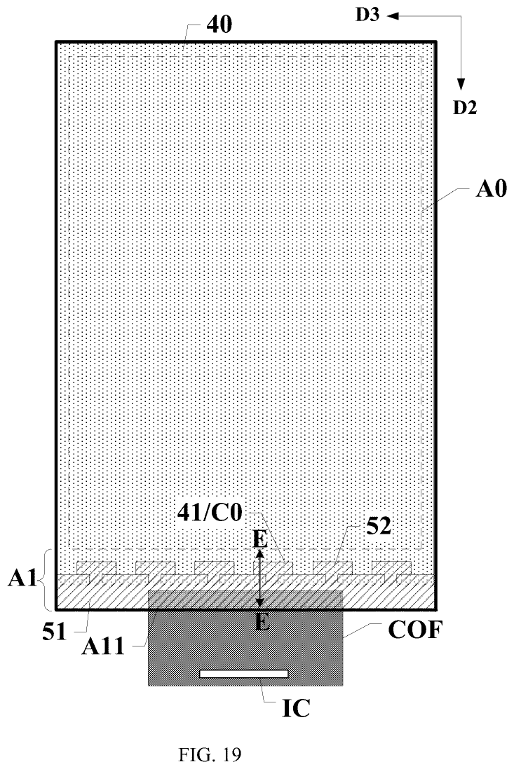

In another embodiment shown in FIG. 19 which is another top view of the display panel, the polarizer 40 may include a limiting groove 41 which may be located at an end of the polarizer 40 facing the binding area A11. The first protective layer 50 may also include a protrusion 52 connected to the main body 51. The protrusion 52 may be located on the side of the main body 51 facing the display area A0, and the protrusion 52 may be located in the limiting groove 41. Along the first direction D1, the at least one groove C0 may overlap with at least part of the limiting groove 41.

In this embodiment, the at least one groove C0 introduced in the first non-display area A1 may include the limiting groove 41 on the polarizer 40, and the at least one groove C0 may at least penetrate the polarizer 40 and the second insulating layer 30. The part of the at least one groove C0 penetrating the polarizer 40 may be used as the limiting groove 41 on the polarizer 40, and the shape of the at least one groove C0 on the polarizer 40 may be adapted to the shape of the limiting groove 41. The shape of the at least one groove C0 penetrating the second insulating layer 30 may be the same as or different from the shape of the limiting groove 41 on the polarizer 40, as long as the at least one groove C0 on the polarizer plane and the at least one groove C0 on the second insulating layer 30 are connected. When the limiting groove 41 on the polarizer 40 is used as the at least one groove C0 penetrating the polarizer 40, the limiting groove 41 may be a structure that may be narrow at the top and wide at the bottom. That is, the width of the part of the limiting groove 41 close to the binding area A11 may be smaller, and the width of the part away from the binding area A11 may be larger. When the first protective layer 50 is filled in the limiting groove 41, the first protective layer 50 located in the limiting groove 41 may form a structure similar to a barb, and the first protective layer 50 as a whole may form a shape similar to a barb. The combination of the two structures may be more conducive to enhancing the traction between the first protective layer 50 and the polarizer 40, thereby further suppressing the shrinkage of the polarizer 40.

In the embodiments shown in FIG. 17 and FIG. 18, when the at least one groove C0 penetrates through the polarizer 40 and the second insulating layer 30, or penetrates through the polarizer 40, the second insulating layer 30 and the first insulating layer 20, the parts of the at least one groove C0 located in different film layers may be designed with the same inner diameter, such that the same size standard may be used to form the at least one groove C0 structure on different film layers. However, the present disclosure is not limited to this. In some other embodiments of the present disclosure, the inner diameters of the parts of the at least one groove C0 in different film layers may also be set to be different.

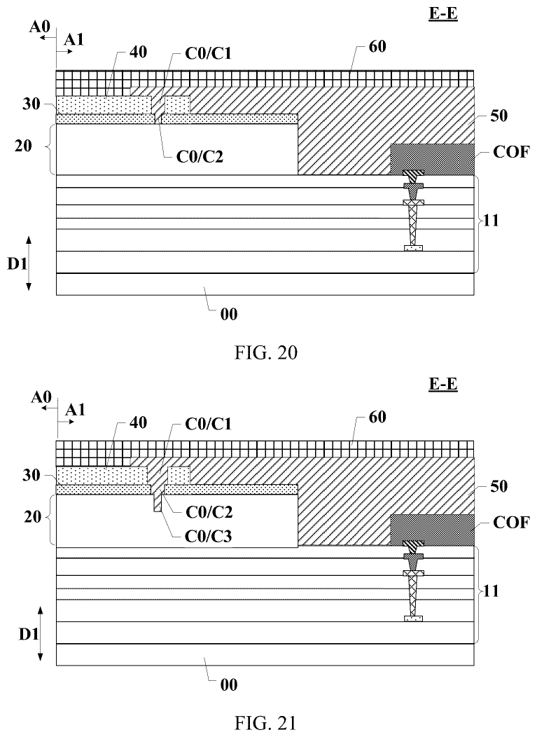

For example, as shown in FIG. 20, which is an EE-direction cross-sectional view of the display panel in the embodiment of FIG. 19, in an optional embodiment of the present disclosure, the at least one groove C0 may include a first groove C1 penetrating through the polarizer 40 and a second groove C2 penetrating through the second insulating layer 30. The first groove C1 and the second groove C2 may be connected, and the inner diameter of the second groove C2 may be smaller than the inner diameter of the first groove C1.

In the embodiment shown in FIG. 20, the inner diameter of the first groove C1 on the polarizer 40 may be larger than the inner diameter of the second groove C2 on the second insulating layer 30, such that the first protective layer 50 in the at least one groove C0 may contact both the inner wall of each of the at least one groove C0 and the surface of the second insulating layer 30 on the side of the second groove C2 facing away from the substrate 00. That is, the first protective layer 50 may contact the longitudinal side walls of the first groove C1 in the polarizer 40 and the second groove C2 in the second insulating layer 30, and contact the horizontal surface of the second insulating layer 30, which may be beneficial to increase the contact area and improve the bonding reliability of the first protective layer 50 with the polarizer 40 and the second insulating layer 30. Therefore, the traction force of the first protective layer 50 on the polarizer 40 and the second insulating layer 30 when the polarizer 40 shrinks may increase, which is more beneficial to suppress the shrinkage of the polarizer 40, and then suppress the shrinkage of the second insulating layer 30 caused by the shrinkage of the polarizer 40, to avoid the crack problem of the second insulating layer 30 caused by the internal shrinkage force of the polarizer 40.

As shown in FIG. 21 which is another EE-direction cross-sectional view of the display panel in the embodiment of FIG. 19, in an optional embodiment of the present disclosure, the at least one groove C0 may further include a third groove C3 located in the first insulating layer 20. The third groove C3 may be connected to the second groove C2, and the inner diameter of the third groove C3 may be smaller than the inner diameter of the first groove C1. Optionally, the third groove C3 may not penetrate the first insulating layer 20, for example, it may only penetrate one or two encapsulation layers in the first insulating layer 20. This embodiment is described by taking the third groove C3 penetrating a film layer in the first insulating layer 20 as an example to ensure that the first insulating layer 20 may still effectively encapsulate the underlying display function layer 10.

In this embodiment, the at least one groove C0 may penetrate through the polarizer 40, the second insulating layer 30 and part of the first insulating layer 20 respectively. At this time, the part of the at least one groove C0 located at the polarizer 40 may be the first groove C1, the part located at the second insulating layer 30 may be the second groove C2, and the part located at the first insulating layer 20 may be the third groove C3. The inner diameters of the first groove C1, the second groove C2 and the third groove C3 may have a decreasing trend. In addition to contacting the longitudinal inner walls of the first groove C1, the second groove C2 and the third groove C3 respectively, the first protective layer 50 in the at least one groove C0 may also contact the surface of the second insulating layer 30 facing away from the substrate 00, and at the same time contact the surface of the first insulating layer 20 facing away from the substrate 00. This design method may be conducive to increasing the contact area between the at least one groove C0 and the three layers of the second insulating layer 30, which is in contact with both the longitudinal surface and the horizontal surface. Therefore, it may be beneficial to the contact reliability of the first protective layer 50 in the at least one groove C0, and may be more conducive to increasing the traction force of the first protective layer 50 on the polarizer 40, the second insulating layer 30 and the first insulating layer 20 when the polarizer 40 shrinks, to suppress the shrinkage of the polarizer 40 and then suppress the shrinkage of the second insulating layer 30 and the first insulating layer 20 caused by the shrinkage of the polarizer 40. Therefore, cracks of the second insulating layer 30 and the first insulating layer 20 because of the internal shrinkage force of the polarizer 40 may be avoided.

Optionally, considering that the display function layer 10 includes signal lines and transistors arranged in the first non-display area A1, when the at least one groove C0 is formed in the first non-display area A1, the aforementioned signal lines and transistors may be avoided. That is, along the first direction D1, the at least one groove C0 may not overlap with the signal lines and transistors, which is conducive to the production of the at least one groove C0 and ensures that the groove C0 may be in good contact with the first protective layer 50.

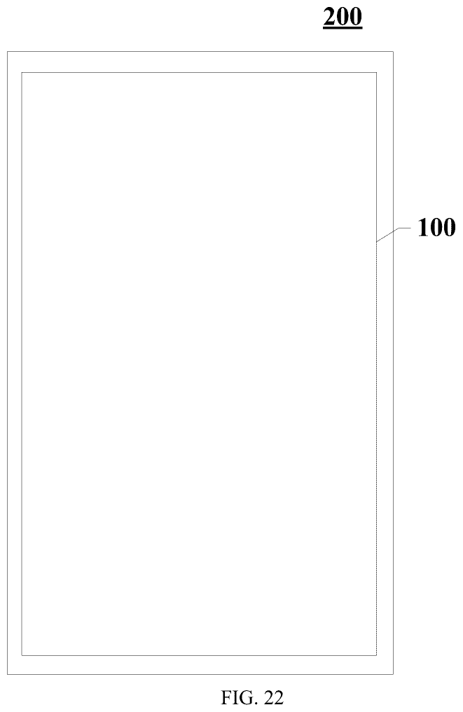

The present disclosure also provides a display device. As shown in FIG. 22 which is a schematic diagram of a structure of a display device consistent with the embodiments of the present disclosure, in one embodiment, the display device 200 may include a display panel 100 provided by any of the above embodiments. The display device 200 provided by the embodiment of the present disclosure may be any electronic device with a display function, such as a tablet computer, a display cabinet display product, a television, or a vehicle-mounted display device. The display device 200 provided by the embodiments of the present disclosure may have the beneficial effects of the display panel 100 provided by the embodiments of the present disclosure. For details, references may be made to the specific description of the display panel 100 in the above embodiments, which will not be repeated here.

The embodiment in FIG. 22 showing the display device in a rectangular structure is used as an example only to illustrate the present disclosure, and does not limit the scope of the present disclosure. In some other embodiments of the present disclosure, the display device 200 may also be embodied as a circle, an ellipse or any other feasible shape, and the present disclosure does not specifically limit this.

In the present disclosure, the display panel and display device provided by the embodiments of the present disclosure may have at least the following technical effects. In the display panel and display device provided by the present disclosure, the second protective layer may be introduced on the side of the polarizer away from the substrate, and the second protective layer may cover the polarizer. That is, along the first direction, the orthographic projection of the second protective layer on the substrate may cover the orthographic projection of the polarizer on the substrate. Optionally, along the first direction, the second protective layer may also overlap with at least part of the first protective layer, which is equivalent to the second protective layer further extending in the direction of the binding area, covering at least part of the first protective layer. That is, the second protective layer may be in direct contact with the first protective layer. In this way, during the reliability test, even if the polarizer shrinks because of the characteristics of its material itself, since the second protective layer and the first protective layer are in direct contact and pull each other, the second protective layer may not shrink with the shrinkage of the polarizer, and the second protective layer may still cover the area between the polarizer and the first protective layer. The second protective layer may isolate external moisture and impurities, and even if the second insulating layer and the first insulating layer are affected by the shrinkage stress of the polarizer and cracks appear, external moisture and impurities may not be able to enter the above-mentioned cracks through the second protective layer, which is beneficial to improving the overall packaging reliability of the display product, and then to improving the performance stability of the display product.

In the present disclosure, relational terms such as “first” and “second” are only used to distinguish one entity or operation from another entity or operation, and do not necessarily require or imply that there is a relationship between these entities or operations. There is no such actual relationship or sequence. Furthermore, the terms “comprises”, “include”, or any other variations thereof are intended to cover a non-exclusive inclusion such that a process, method, article, or apparatus that includes a list of elements includes not only those elements, but also those not expressly listed, or elements inherent to the process, method, article or equipment. Without further limitation, an element defined by the statement “comprises a . . . ” does not exclude the presence of additional identical elements in a process, method, article, or apparatus that includes the stated element.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A display panel, comprising:
a substrate;
a display function layer, a first insulating layer, a second insulating layer, and a polarizer disposed on a same side of the substrate; and
a first protective layer and a second protective layer,
wherein:
along a first direction, the first insulating layer is disposed on a side of the display function layer away from the substrate, the second insulating layer is disposed on a side of the first insulating layer away from the substrate, and the polarizer is disposed on a side of the second insulating layer away from the substrate, wherein the first direction is perpendicular to a plane where the substrate is located;
the display panel has a display area and a first non-display area located on one side of the display area along a second direction;
the first non-display area includes a binding area;
the polarizer is located in the display area and at least a portion of the first non-display area;
the second insulating layer and the first insulating layer are located in the display area and at least a portion of the first non-display area;
along the first direction, the polarizer, the second insulating layer, and the first insulating layer do not overlap with the binding area;
the first protective layer is located in the first non-display area;
along the first direction, the first protective layer is at least located on the side of the second insulating layer away from the substrate, and overlaps with the second insulating layer, the first insulating layer and the binding area;
the second protective layer is located on a side of the polarizer away from the substrate and covers the polarizer; and
along the first direction, the second protective layer overlaps with at least part of the first protective layer.

2. The display panel according to claim 1, wherein:
the substrate is a rigid substrate.

3. The display panel according to claim 1, wherein:
the first protective layer includes a main body and protrusions connected to the main body, wherein the protrusions are located on a side of the main body facing the display area; and
the polarizer includes limiting grooves, wherein the limiting grooves are located at an end of the polarizer facing the binding area and the protrusions are located in the limiting grooves.

4. The display panel according to claim 3, wherein:
one limiting groove includes a first portion and a second portion arranged along the second direction, wherein the second portion is located between the first portion and the binding area; and
along a third direction, a maximum width of the first portion is larger than a maximum width of the second portion, wherein the third direction is parallel to the plane where the substrate is located and perpendicular to the second direction.

5. The display panel according to claim 4, wherein:
orthographic projections of the first portion and the second portion on the plane where the substrate is located are both rectangular; and
along the second direction, a depth of the first portion is F, and a total depth of the limiting groove is A, wherein F:A≥3:5.

6. The display panel according to claim 3, wherein:
in the polarizer, the multiple limiting grooves are arranged along a third direction, wherein the third direction is parallel to the plane where the substrate is located and perpendicular to the second direction; and
along the third direction, a maximum width of one limiting groove is S1, and a minimum distance between a first edge of the polarizer and one limiting groove adjacent to the first edge is S0, wherein S0≤S1 and the first edge extends along the second direction.

7. The display panel according to claim 3, wherein:
in the polarizer, the multiple limiting grooves are arranged along a third direction, wherein the third direction is parallel to the plane where the substrate is located and perpendicular to the second direction;
along the second direction, a depth of one limiting groove is A;
along the third direction, a minimum spacing width between two adjacent limiting grooves is E;
one limiting groove includes a first opening, wherein the first opening is located on a side wall of the polarizer facing the binding area; and
along the third direction, the width of the first opening is C, wherein A=E=C.

8. The display panel according to claim 7, wherein:
the limiting groove further includes a first groove bottom arranged opposite to the first opening along the second direction; and
along the third direction, a minimum distance between the edge of the first groove bottom and the edge of the first opening is B, wherein B=C.

9. The display panel according to claim 1, further comprising elastic pads disposed in the first non-display area, wherein:
the elastic pads extend along a third direction, wherein the third direction is parallel to the plane where the substrate is located and perpendicular to the second direction;
in the first non-display area, the elastic pads are disposed between the first insulating layer and the second insulating layer;
the second insulating layer includes convex portions, wherein the convex portions overlap with the elastic pads along the first direction and a distance between the convex portions and the substrate is larger than a distance between the second insulating layer and the substrate in the display area.

10. The display panel according to claim 9, wherein:
a first cross-section of the elastic pads is in an arc shape or a trapezoidal shape, wherein the first cross-section is perpendicular to the plane where the substrate is located and parallel to the second direction.

11. The display panel according to claim 10, wherein:
the elastic pads have an initial state and a stretched state;
in the initial state, a height of the elastic pads is larger than the height of the elastic pads in the stretched state; and
in the initial state, a maximum width of the first cross-section of the elastic pads along the second direction is L0, wherein L0≥0.1mm.

12. The display panel according to claim 11, wherein:
along the second direction, the elastic pads are located between the polarizer and the binding area; and
in the initial state, a minimum distance between the elastic pads and the polarizer is L2, and a minimum distance between the elastic pads and the binding area is L3, wherein L2≥0.2mm and L3≥0.2mm.

13. The display panel according to claim 11, wherein:
at least two of the elastic pads are arranged along the second direction; and
in the initial state, a distance between adjacent elastic pads along the second direction is L4, wherein L4≥0.1 mm.

14. The display panel according to claim 11, wherein:
in the initial state, a height of the first cross section of the elastic pads along the first direction is L1, wherein L1≥0.05 mm.

15. The display panel according to claim 1, further comprising at least one groove in the first non-display area, wherein:
along the first direction, the at least one groove at least penetrates the polarizer and the second insulating layer;
the first protective layer includes a main body and an extension portion connected to the main body, wherein the extension portion is at least located in the at least one groove.

16. The display panel according to claim 15, wherein:
the first protective layer further includes a connecting portion connecting the main body and the extending portion, wherein at least a portion of the connecting portion is located on the side of the polarizer away from the substrate; and
along the first direction, the second protective layer covers the first protective layer.

17. The display panel according to claim 15, wherein:
the polarizer includes a limiting groove, wherein the limiting groove is located at the end of the polarizer facing the binding area;
the first protective layer further includes a protrusion connected to the main body, wherein the protrusion is located on a side of the main body facing the display area and the protrusion is located in the limiting groove; and
along the first direction, the at least one groove overlaps with at least part of the limiting groove.

18. The display panel according to claim 15, wherein:
the at least one groove includes a first groove penetrating the polarizer and a second groove penetrating the second insulating layer, wherein the first groove is connected to the second groove and an inner diameter of the second groove is smaller than an inner diameter of the first groove.

19. The display panel according to claim 18, wherein:
the at least one groove further includes a third groove located in the first insulating layer, wherein the third groove is connected to the second groove and an inner diameter of the third groove is smaller than an inner diameter of the first groove.

20. A display device, comprising a display panel, wherein:
the display panel includes a substrate;
a display function layer, a first insulating layer, a second insulating layer, and a polarizer arranged on a same side of the substrate; and
a first protective layer and a second protective layer,
wherein:
along a first direction, the first insulating layer is located on a side of the display function layer away from the substrate, the second insulating layer is located on a side of the first insulating layer away from the substrate, and the polarizer is located on a side of the second insulating layer away from the substrate, wherein the first direction is perpendicular to a plane where the substrate is located;
the display panel has a display area and a first non-display area located on one side of the display area along a second direction;
the first non-display area includes a binding area;
the polarizer is located in the display area and at least a portion of the first non-display area;
the second insulating layer and the first insulating layer are located in the display area and at least part of the first non-display area;
along the first direction, the polarizer, the second insulating layer, and the first insulating layer do not overlap with the binding area;
the first protective layer is located in the first non-display area;
along the first direction, the first protective layer is at least located on the side of the second insulating layer away from the substrate, and overlaps with the second insulating layer, the first insulating layer and the binding area;
the second protective layer is located on the side of the polarizer away from the substrate and covers the polarizer; and
along the first direction, the second protective layer overlaps with at least part of the first protective layer.
